(19) United States
(12) Patent Application Publication
(10) Pub. No.: US 2017/0182522 A1
(43) Pub. Date: Jun. 29, 2017

(54) TREATMENT METHOD AND DEVICE USING A SUPERCRITICAL FLUID AND A DISCHARGE STORAGE VOLUME

(71) Applicant: DFD - DENSE FLUID DEGREASING, Le Bourget du Lac (FR)

(72) Inventor: Alain CHAVRIER, Bourgoin Jallieu (FR)

(21) Appl. No.: 15/312,819

(22) PCT Filed: May 28, 2015
(86) PCT No.: PCT/EP2015/061889

§ 371 Date: Nov. 21, 2016

(30) Foreign Application Priority Data
May 28, 2014 (FR) 1454886

(51) Int. Cl. B08B 7/00; H01L 21/67; B08B 3/04; H01L 21/02; B01J 3/04; B08B 3/02

(52) U.S. Cl. CPC B08B 7/0021; B01J 3/04; B08B 3/02; B08B 3/045; H01L 21/02101; H01L 21/67051

(57) ABSTRACT

A treatment device using a supercritical fluid comprises: a chamber for receiving the parts to be treated, provided with means for establishing fluid communication and isolating the inside of the chamber with respect to the outer atmosphere, supercritical fluid supply means, means for storing some of the gas contained in the chamber at a pressure lower than that of the chamber after a cleaning step and before fluid communication is established between the inside of the chamber and the outer atmosphere.

### TECHNICAL FIELD AND STATE OF THE PRIOR ART

The invention relates to treatment techniques, in particular extraction, for example cleaning, of parts or objects by implementation of a dense fluid, for example supercritical, notably carbon dioxide.

A cleaning technique is known from the document WO 02/32593.

A known device for implementing such a technique will be described with reference to the schematic representation of FIG. 1.

This device is supplied with a liquefied gas, which comes for example from a reserve, or cylinder 2, in which it is maintained at a temperature of, for example, −20° C.

This reserve 2 makes it possible to supply a storage chamber 6, which stores both gas in gaseous form and liquefied gas, via a pump 3 or a filling compressor and a valve 6₁. In this chamber, the gas is heated by heating means 7, which is going to make it possible to increase its temperature, for example to 20° C., and to bring it to a pressure of several tens of bars, for example around 60 bars.

Liquefied gas, withdrawn from this chamber 6 using a valve 6₃, may then be taken, by means 8, under thermodynamic conditions enabling it to be used as cleaning fluid in the cleaning chamber 14, also called autoclave. In particular, the means 8 may comprise pumping means 10 and heating means 12. In the case where the fluid is CO₂, the pump 10 makes it possible to bring the fluid coming from the reserve 6 to a pressure greater than 73.85 bars, and the heating means 12 make it possible to bring the temperature of the fluid to a value greater than 31° C., these conditions assuring the fluid is in a supercritical state.

In the autoclave, the fluid may be used in accordance with the teaching of document WO 02/32193. The autoclave 14 is provided with a door 15 that is going to make it possible to introduce therein the parts to be cleaned. After closing the door, the fluid is introduced under pressure, at around 120 bars, and the parts are cleaned by the action of the fluid.

In the course of a cleaning cycle, the fluid is then evacuated, depressurised by the depressurisation means 16 (mainly comprising a regulation valve 16₂ and a valve 16₁), then sent to the means 18 forming a separator, which are going to make it possible to separate the gas from particles and dirt that have been recovered during the cleaning and with which the gas is loaded.

The gas thus treated may then be conveyed to liquefaction means 19, then again stored in liquid form in the chamber 6.

A cleaning cycle implemented with this type of device is too long for implementation at a truly industrial scale.

Furthermore, such a device consumes too much gas.

More precisely, during a cleaning cycle, after introduction of the parts to be cleaned into the autoclave 14 then closing the door 15 thereof, but before the start of the cleaning cycle, gas is introduced into the autoclave, at a pressure of the order of several bars. This gas comes from the chamber 6. To this end, a valve 6₂ is arranged on a path defined by a conduit 9 that connects an upper part of the chamber 6 and a point arranged between the pump 10 and the heating means 12. This valve and this conduit make it possible to withdraw gas, in gaseous form. This gas is then heated by the means 12. If it is not wished to heat the gas, it is possible that the means 9 are connected directly to the means 27 or even directly in the means 14.

This step makes it possible, when the dense fluid gas is then introduced, under pressure, from the means 8, to avoid that it is under conditions that can lead to the formation of a block of ice (this is the phenomenon, in the case of carbon dioxide, of formation of dry ice; in fact, the triple point of CO₂ is at −56° C., 5 bars), which is to be avoided because this ice may be very difficult to eliminate rapidly.

But this technique leads:
to a risk of cavitation of the pump 10: due to the initial consumption of gas, the pressure, but also the temperature, of the chamber 6 have decreased, which can lead to such cavitation problems; in order to limit them as much as possible, the volume of the chamber 6 must be as large as possible, which is costly, or instead the filling of the chamber 14 must be slow, which is not acceptable,
to a loss of time, because the gas thus consumed must be reintroduced into the system, for example by supply of the chamber 6 from the reserve 2; the step of heating with the means 7 implies a duration that increases the duration of an operating cycle of the machine.

Furthermore, at the end of the cleaning cycle, the door 15 (or instead the valve 14₂) of the chamber 14 is open, and the gas contained in the latter is sent into the atmosphere. The result is an important loss of this gas.

Consequently, both from the point of view of the duration for implementing a cycle, and from the consumption of fluid, such a known device cannot be implemented at a truly industrial scale.

### DESCRIPTION OF THE INVENTION

The invention aims to resolve these problems.

According to the invention a treatment device using a dense fluid, for example a fluid in the supercritical state, comprises:

a) a cleaning chamber, also called autoclave, for receiving the parts to be treated,

b) means for supplying dense or supercritical fluid to said treatment chamber, comprising first fluid storage means,

c) second storage means arranged at the outlet of the treatment chamber (also called discharge storage volume),

d) means, for example one or more valves, for establishing fluid communication between the treatment chamber and said second storage means.

Thus fluid circulation is enabled between the treatment chamber and said second storage means. A first flow of fluid is thus going to circulate, from the cleaning chamber to said second storage means, then, conversely, along a path opposite to that followed by the first flow, a second flow of fluid is going to circulate from the second storage means to the cleaning chamber.

This circulation will take place by pressure difference between the two volumes concerned: when the pressure in the cleaning chamber is greater than that in the second storage means, the fluid circulates from the cleaning chamber to the second storage means; when the pressure in the cleaning chamber is lower than that in the second storage means, the fluid circulates from the second storage means to the cleaning chamber.

Means may be specially programmed to make a fluid circulate from the cleaning chamber to said second storage means, then, conversely, from the second storage means to the cleaning chamber.

The second storage means make it possible to store, at a pressure P₂, some of the gas that is contained in the treatment chamber at pressure P₁ (P₁>P₂), after a treatment step and before fluid communication is established between the inside of the chamber and the outer atmosphere, notably by opening the door of the chamber and before fluid communication is established between the treatment chamber and the storage means.

Here and in the remainder of the document, the expression “establishing fluid communication”, applying to 2 volumes, signifies that a fluid can circulate, or flow, from one volume to the other. The means of establishing fluid communication are also means for interrupting this fluid communication, that is to say to stop any possibility of flow of fluid from one volume to the other.

The transfer of gas, between the second storage means and the treatment chamber, in one sense or in the other, is carried out using the means for establishing fluid communication, for example by opening one or more of said valves. This transfer is carried out without pumping means, under the simple action of the pressure in the two volumes placed in communication, for example up to equilibrium of the pressures between these two volumes.

The invention enables recovery of some of the gas used, without energy input, and without moving parts, apart from the valves.

The second storage means are different to the first storage means. They may moreover be different to the first storage means by their volume, and/or the pressure at which the gases are stored therein, etc.

The second storage means then enable a re-use of the gas stored for various applications.

In particular, some of the fluid thereby stored may be reused, at the start of the following treatment cycle, while being reinjected into the treatment chamber. This step:
is carried out after loading the parts or the material to be treated into the treatment chamber, then isolating the inside of the chamber with respect to the outer atmosphere, notably by closing the means of fluid communication between the inside of the chamber and the outer atmosphere, in particular the door of this chamber, but before introduction of dense fluid and before the start of the treatment,
leads to a distribution of the gas stored in said second storage means, both in these storage means and in said treatment chamber, at a pressure P₃ lower than the storage pressure P₂ in the storage means.

For the implementation of this step, the means for establishing fluid communication are actuated, as indicated above.

The pressure in the treatment chamber then increases, from atmospheric pressure to a pressure P₃, lower than the storage pressure P₂ in the second storage means, whereas the pressure in the second storage means decreases, from the storage pressure P₂ to, for example, the pressure P₃.

This filling of the autoclave with gas, at the start of the cleaning cycle, may be very rapid.

Moreover, this possibility makes it possible to have a smaller main storage volume.

Furthermore, some of this fluid thus stored may be used to actuate at least some of the pneumatic control elements of the system. Another fluid (for example compressed air) normally used to actuate said pneumatic elements (valve and/or jack and/or pump) is thus economised.

For this reason, a device according to the invention may comprise means for conveying at least some of the fluid stored in the second storage means to one or more pneumatically controlled valves (and/or jacks and/or pumps).

Finally, some of this fluid thus stored may be compressed, liquefied and injected into the first fluid storage means.

To this end, a device according to the invention may moreover comprise means for conveying at least some of the fluid stored in the second storage means to the means for supplying said treatment chamber (or to the first storage means), preferably during a treatment cycle.

Another advantage linked to the storage of the fluid that remains in the treatment chamber at the end of the cycle is the following. The rapid evacuation of the chamber at the end of the cycle has the immediate consequence of the release, into the atmosphere, of the fluid that it contains at the moment of this evacuation. This rapid release is accompanied by a high noise level. Due to the fact of the transfer of some of the gas from the treatment chamber to the second storage means, before evacuation of the chamber, the quantity of gas released into the atmosphere is reduced, which leads to a reduction in the sound volume linked to this step, compared to the case where no volume of gas from the treatment chamber is transferred into storage means outside of the chamber.

The second storage means may have an internal volume less than, or greater than, or identical to, or close to, that of the treatment chamber, for example equal to the latter +10%. The efficiency increases with the size of these second storage means. The second storage means may be arranged:
in parallel, or at the outlet, of the means that make it possible to depressurise a gas at the outlet of said chamber,
and/or, in the sense of circulation of fluid from said chamber, upstream of the separator forming means.

Means may be provided for heating the second storage means, in order that the gas that is stored therein does not liquefy.

The invention also relates to a treatment method using a dense fluid, implementing a device according to the invention, in particular of the type such as described above.

The invention also relates to a treatment method using a dense fluid, potentially supercritical, comprising:

a) the introduction of at least one first part to be treated, into a chamber, provided with an opening and closing door (or, more generally, means for establishing fluid communication between the chamber and the outer atmosphere), then closing this door (or, more generally, stopping or closing the fluid communication between the chamber and the outer atmosphere),

b) the supply of dense fluid to said chamber and the treatment of said part,

c) the storage of some of the gas contained in the chamber, in the storage means, at a pressure P₂ lower than that, P₁, which exists in the chamber, after treatment step

b) and before opening the door of the chamber (or, more generally, before fluid communication is established between the chamber and the outer atmosphere),

d) then the opening of said door, or, more generally, establishing fluid communication between the chamber and the outer atmosphere.

Such a method may then moreover comprise, in this order:

e) the introduction of at least one second part to be treated into said chamber, then closing said door (or, more generally, stopping or closing the fluid communication between the chamber and the outer atmosphere),

f) then the injection, into said chamber, of at least some of the gas stored in said storage means, the gas contained in said chamber then being at a pressure Pa lower than the storage pressure Ps in the storage means.

Fluid circulation thus takes place between the treatment chamber and said second storage means. A first flow of fluid circulates, from the cleaning chamber to said second storage means, then, conversely, along a path opposite to that followed by the first flow, a second flow of fluid circulates from the second storage means to the cleaning chamber.

This circulation results from the difference in pressure between the two volumes concerned: when the pressure in the cleaning chamber is greater than that in the second storage means, the fluid circulates from the cleaning chamber to the second storage means; when the pressure in the cleaning chamber is lower than that in the second storage means, the fluid circulates from the second storage means to the cleaning chamber.

The invention also relates to a treatment method using a dense fluid, potentially supercritical, comprising:

a) the introduction of at least one first part to be treated, into a chamber, provided with an opening and closing door (or, more generally, means for establishing fluid communication between the chamber and the outer atmosphere), then closing this door (or, more generally, stopping or closing the fluid communication between the chamber and the outer atmosphere),

b) the supply of dense fluid to said chamber and the treatment of said part,

c) the storage of some of the gas contained in the chamber, in (second) storage means, at a pressure P₂ lower than that, P₁, which exists in the chamber, after treatment step b) and before opening the door of the chamber (or, more generally, before fluid communication is established between the chamber and the outer atmosphere),

d) then, later, fluid circulation from said second storage means to the treatment chamber.

A first flow of fluid is thus going to circulate, from the cleaning chamber to said second storage means, then, conversely, along a path opposite to that followed by the first flow, a second flow of fluid is going to circulate from the second storage means to the cleaning chamber.

Such a method may moreover comprise an injection or a transfer of some of the gas stored in said storage means (or second storage means) into main storage means, (or first storage means) arranged upstream of the means for conveying a fluid in a supercritical state. Preferably, this injection takes place at least in part during a treatment cycle.

A method according to the invention may moreover comprise the actuation of one or more pneumatic control elements using some of the gas stored in said storage means.

It is possible to heat the second storage means, in order that the gas stored therein does not liquefy.

The (second) storage means and the injection means may be arranged in parallel with the means that make it possible to depressurise a gas at the outlet of said chamber.

These (second) storage means and said injection means may be arranged at the outlet of the means that make it possible to depressurise a gas at the outlet of said chamber.

In a method according to the invention, the part to be treated may be at least in part made of a metal material, and/or a metal alloy, and/or a ceramic material, and/or a semiconductor material, and/or a textile material and/or a natural material.

The treatment may be an extraction treatment, for example cleaning or degreasing, or debinding, or sterilisation, or impregnation, or deposition.

The invention also relates to a computer programme comprising instructions for implementing a method according to the invention, in particular such as described above.

The invention also relates to a data support, which can be read by a computer system, comprising data, in coded form, for implementing a method according to the invention, in particular such as described above.

The invention also relates to a software product comprising programme data support means, capable of being read by a computer system, making it possible to implement a method according to the invention, in particular such as described above.

A device according to the invention, as defined above, may be controlled, or a method according to the invention, as defined above, may be controlled or implemented, by specially programmed means to make a fluid circulate from the cleaning chamber to the second storage means, then, conversely, or along an opposite path, from the second storage means to the cleaning chamber.

### BRIEF DESCRIPTION OF THE DRAWINGS

FIG. 1 is a diagram of a cleaning machine using a supercritical fluid, of known type,

FIG. 2 is a diagram of an embodiment of a cleaning machine using a supercritical fluid, according to the invention,

FIG. 3 is a diagram of another embodiment of a cleaning machine using a supercritical fluid, according to the invention,

FIGS. 4A and 4B are variants of a cleaning machine using a supercritical fluid, according to the invention,

FIG. 5 is a schematic representation of the means for controlling a machine according to the invention.

### DETAILED DESCRIPTION OF PARTICULAR EMBODIMENTS

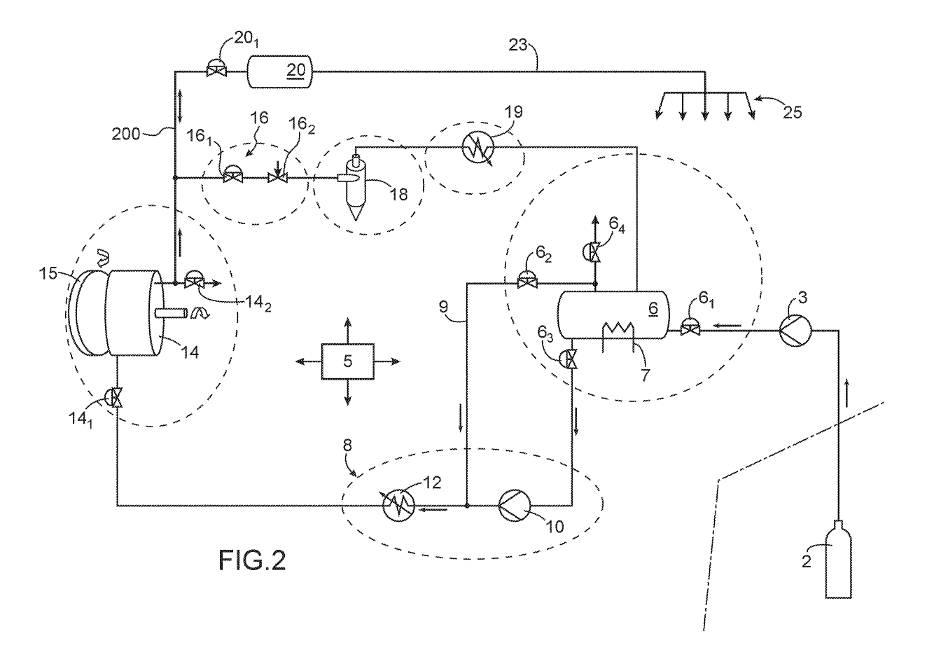

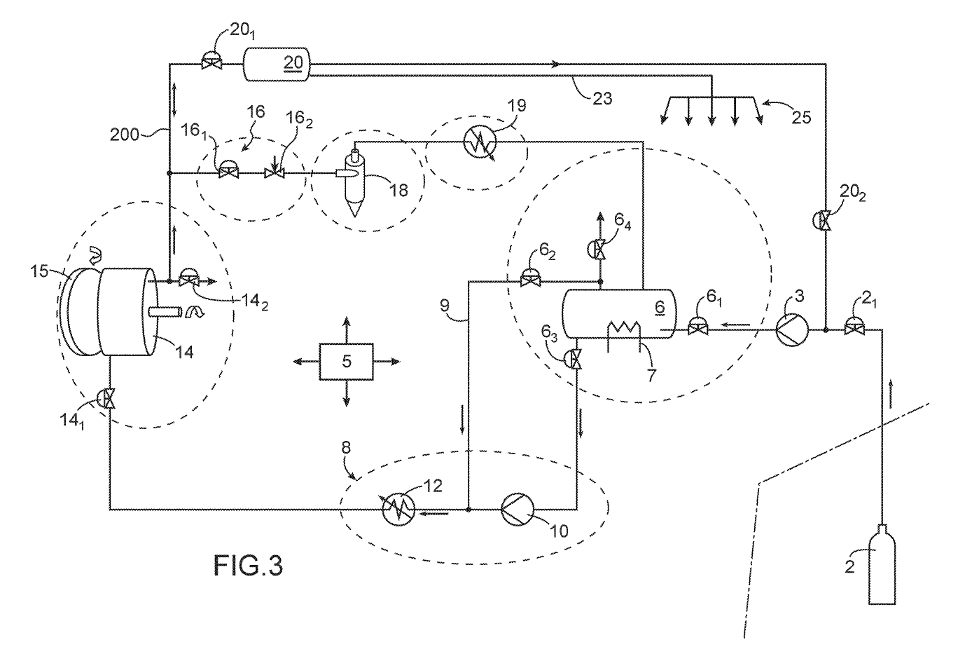

In FIGS. 2 and 3 are represented an example of embodiment of a machine according to the invention.

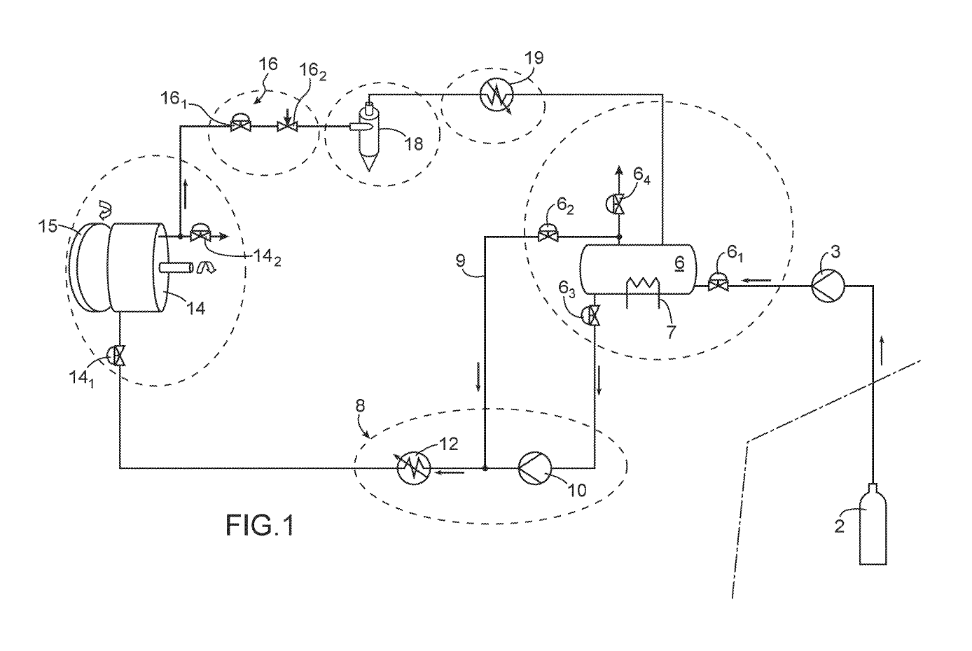

Numerical references identical to those of FIG. 1 designate therein identical or corresponding elements. In particular, this machine comprises a storage chamber 6 (or first storage means), provided to store liquefied gas, at several tens of bars, for example 60 bars. This chamber may be supplied by a reserve 2, which has for example the shape of a vat (which contains the gas and also potentially liquefied gas at, for example, 20 bars), to which the device may be connected, and liquefaction means (not represented in the figures) being able to be provided at the outlet of this reserve, to form a liquefied gas that is then stored in the chamber 6.

An autoclave 14, or cleaning chamber, receives the parts to be cleaned. This chamber is provided with a door 15, through which the parts may be introduced into the chamber, then, after cleaning, extracted from the chamber. It may also be provided with a vent, or a conduit forming a vent, and a valve 14₂. Means for, potentially, making this autoclave move, as well as means for receiving baskets that are going to contain the parts to be cleaned, are described in the document WO 02/32593.

Means 8, comprising for example a pump 10 and heating means 12 make it possible to convey the fluid, withdrawn from the chamber 6, under thermodynamic conditions enabling it to be used as cleaning fluid in the cleaning chamber 14. In the case where the fluid is CO₂, the pump 10 makes it possible to bring the fluid from the reserve 6 at a pressure greater than 73.85 bars, and the heating means 12 make it possible to bring the temperature of the fluid to a value greater than 31° C., these conditions then assuring that the fluid is in a so-called supercritical state.

Means 16 make it possible to depressurise the gas at the outlet of the autoclave 14.

Means 18, forming a separator, make it possible to separate the gas from the impurities that it transports and which result from a preceding or underway cleaning operation.

The whole of these means make it possible to carry out a cleaning cycle, that is to say a series of steps, which mainly include:

a) the loading of the parts into the autoclave 14,

b) the closing of the door 15, and potentially the valve 14₂ (or, more generally, stopping or closing the fluid communication between the chamber and the outer atmosphere),

c) the cleaning of the parts by the action of the dense fluid on the parts to be cleaned; this step is carried out at high pressure P₀, for example greater than 100 bars, again for example at around 120 bars for supercritical CO₂,

d) after cleaning, the reduction of the pressure in the chamber, from P₀ to a value P₁, substantially lower than P₀; P₁ is for example of the order of several tens of bars, or instead comprised between 50 bars and 90 bars, or instead between 60 and 70 bars, for example close to the pressure in the storage 6.

e) the opening of the door (or, more generally, establishing fluid communication between the chamber and the outer atmosphere), and the unloading of the parts; the internal volume of the autoclave is then at atmospheric pressure.

But the device here comprises, moreover, second storage means 20 (or storage volume, different to each of the means 6, 18) that are going to make it possible to store some of the gas that is contained in the autoclave 14 at the end of the cleaning cycle, before opening the door 15 (step e) (or, more generally, before fluid communication is established between the chamber and the outer atmosphere), at the pressure P₁ indicated above. These two volumes are connected by a conduit 200. The gas is then no longer under conditions enabling it to be in the dense state, or, for CO₂, supercritical state. A set of valves 16₁, 20₁ is going to make it possible to direct, during a predetermined duration, the flow of gas coming from the autoclave 14 to these storage means 20 via the conduit 200 that connects them. These means 20 may moreover be provided with pressure measurement means.

In the embodiment of FIG. 3, at the outlet of these means 20, means 20₂, for example a valve, make it possible to send some of the gas stored in the means 20, downstream, to the means for supplying the chamber 6. During the operation of filling the means 20, these means 20₂ will preferably be closed.

Preferably, the means 20 have an internal volume greater than or equal to the internal volume of the autoclave 14. This volume is for example of the order of several tens of litres, for example comprised between 50 l and 100 l. Again for example, for an autoclave of which the internal volume is around 85 l, the internal volume of the means 20 may also be around 85 l.

If the chamber 14 has for internal volume Vₐ, and if the means 20 have for internal volume Vᵣ, then the proportion of gas stored, and thus economised, in the means 20 tends towards Vᵣ/(Vₐ+2Vᵣ), after complete opening of the valve 20₁. This volume tends towards 50% for a volume Vᵣ very large compared to Vₐ, and towards 33% if Vᵣ=Vₐ. There is thus interest in having a volume of the means 20 that have a storage capacity that is a large as possible, but it is obviously necessary to target an economic optimum.

These storage means 20 may be arranged in parallel with depressurisation means 16 of the gas that comes out of the autoclave. The path followed by the gases at the outlet of the autoclave depends on the actuation of the valves 16₁, 20₁: if the valve 16₁ is open, the gas is sent to the depressurisation means 16, and follows its normal path, to the separator forming means 18. When this valve 16₁ is open, the valve 20₁ is closed. The opening of the latter is preceded by the closing of the valve 16₁. Temporarily, the gas is then no longer directed to the depressurisation means, but to the storage means 20. During the injection of gas, from the means 20 to the autoclave 14, the valve 16₁ is closed and the valve 20₁ is opened. Generally, the valve 16₁ is closed and the valve 20₁ is opened except if it is wished to use the gas from the reservoir 20 to pre-fill the volumes 18 and potentially 6.

At the end of the filling of the means 20, in the manner explained above, the pressure P₂ in the autoclave 14, before opening of the valve 14₁, may be, for example, substantially identical to that attained in the storage means 20. As already indicated above, this pressure is substantially lower than the pressure P₁ usually obtained at the end of a cleaning cycle (for example around 60 bars), before opening the door 15. For example, P₂ is comprised between, on the one hand, P₁ and, on the other hand, P₁/2.

More generally, if the chamber 14 has for internal volume Vₐ, and if the means 20 have for internal volume Vᵣ, then the pressure obtained after complete opening of the valve 20₁ is comprised between P₁Vₐ/(Vₐ+Vᵣ) at the first cycle (Vᵣ is then initially, or before the first cycle, empty) and P₁(Vₐ+Vᵣ)/(Vₐ+2Vᵣ) after a large number of cycles. Consequently, the gas, which is in the autoclave 14 at the end of the cleaning cycle, passes successively:
firstly from the pressure P₁ to the pressure P₂ (pressure that may be substantially identical in the autoclave 14 and in the means 20), which is lower than the pressure P₁, and which may be comprised within the aforementioned range,
then, when it is re-injected, from the means 20, into the autoclave 14 which is then at atmospheric pressure, from the pressure P₂ to a pressure P₃, which is itself lower than the pressure P₂; the pressure obtained after complete opening of the valve 20₁ is P₂Vᵣ/(Vₐ+Vᵣ).

It may also be noted that the passage from a first pressure P₁ (respectively P₂) to a second pressure P₂ (respectively P₃), lower than the first, does not require any pressure reducer, the depressurisation being assured by the distribution of the gas from a first volume to a global volume that is greater than the first volume. In other words: the total volume constituted by the chamber 14 and the means 20 is greater, on the one hand, than the single volume of the chamber 14 and, on the other hand, than the single volume of the means 20; the establishment of communication between the two volumes assures, as a function of the duration of opening of the valves, the distribution of gas between them and, at the most, equilibrium of pressures between them.

After distribution of the gases between the chamber 14 and the storage means 20, then closing of the valve 20₁, it is possible to open the valve 14₂ (or the door 15) of the autoclave, in order to release the remainder of the cleaning gas which the latter still contains. The pressure in the autoclave is thus brought back to atmospheric pressure (step e) above). The gas, which has been accumulated in the storage means 20, then remains stored in the latter and is not evacuated therefrom.

An initial filling of the means 20 may be carried out at the end of a first cleaning cycle, by opening of the valve 20₁, the gas then being distributed between the two volumes 14, 20, then closing of this same valve. It is then possible to open the valve 14₂, then the door 15.

During a following cleaning cycle, after introduction of the parts to be cleaned into the autoclave 14 (step a), and after closing the door 15 (step b) thereof (or, more generally, after stopping or closing the fluid communication between the chamber and the outer atmosphere), but before the introduction of dense fluid into the autoclave 14, some of the gas accumulated in the means 20 may be introduced into the autoclave, by opening the valve 20₁. Some of the gas stored in the means 20 thus returns to the chamber 14, along a path opposite to that followed by the gas when it has migrated from the chamber 14 to the means 20. This gas thus passes again through the conduit 200, but in the opposite sense. The exact quantity depends on the degree of opening of the latter and its opening duration. For example, the autoclave is filled with this gas at a pressure of the order of several bars, again for example comprised between 5 and 15 bars or even 10 bars or even more.

This step makes it possible, when the dense fluid gas is introduced, under pressure, from the means 8, to avoid that it is under conditions that could lead to the formation of a block of ice (this is the phenomenon, in the case of carbon dioxide, of formation of dry ice), which is to be avoided because this dry ice may be very difficult to eliminate rapidly.

Consequently, according to this technique, some of the gas stored in the storage means 20 is used during a preceding cleaning cycle, to reinject it into the autoclave 14 during, or at the start, of the following cleaning cycle. This makes it possible to reuse some of the gas that has already been used during the preceding cycle. Moreover, this step is practically instantaneous, by simple opening of the valve 20₁. No pump, nor any pumping step, is necessary to introduce the gas, which comes from the autoclave 14, into the storage means 20 and, vice versa, to send the gas stored in the latter back to the autoclave 14, at the start of the following cleaning cycle.

The invention makes it possible to carry out a cleaning cycle that comprises the following steps:

a) loading the parts into the autoclave 14,

b) closing the door 15 (or, more generally, stopping the fluid communication, or closing the means for establishing fluid communication, between the chamber and the outer atmosphere), the internal volume of the autoclave 14 then being at atmospheric pressure,

b₁) injecting gas into the autoclave 14, from the means 20; or, more precisely, establishing fluid communication between the chamber 14 and the storage means 20, accompanied by the transfer of some of the gas contained in the storage means 20 to the chamber 14 and a variation in pressure between these two volumes (the pressure in the chamber 14 increases, whereas the pressure in the means 20 decreases), then the isolation of the chamber 14 with respect to the storage means 20,

c) then the introduction, into the autoclave 14, of dense fluid, and the cleaning of the parts by action of this dense fluid on the parts to be cleaned; this step is carried out at high pressure P₀, for example greater than 100 bars, again for example at around 120 bars for supercritical CO₂,

d) the reduction of the pressure in the chamber, from P₀ to a value P₁, substantially lower than P₀; P₁ is for example of the order of several tens of bars, or instead comprised between 50 bars and 90 bars, or instead between 60 and 70 bars,

d₁) establishing fluid communication between the chamber 14 and the storage means 20, accompanied by the transfer of some of the gas contained in the chamber 14 to the storage means 20, and the variation in pressure between these two volumes (the pressure in the chamber 14 decreases, whereas the pressure in the means 20 increases), then the isolation of the chamber 14 with respect to the storage means 20,

e) finally, opening the door (or, more generally, establishing fluid communication between the chamber and the outer atmosphere) and unloading the parts; the internal volume of the autoclave is then at atmospheric pressure.

It may be noted that, during step c), the dense fluid may be introduced into the autoclave continually by the means 20; at the outlet of the autoclave, it may be depressurised by the means 16, cleaned by the means 18, liquefied by the means 19 and sent back into the means 6 to be reused; this may be repeated or implemented continually up to the end of the treatment. Dense fluid may thus be recycled continually.

The fact of storing some of the gas in the means 20, available at the end of the cycle in the autoclave 14, also makes it possible to reduce the quantity of gas that is going to escape from the latter when the valve 14₂ is opened (step e). This leads, notably, to a reduction in the acoustic effect, thus, practically, to a reduction in noise, which accompanies the escape of gas from the chamber.

Some of the gas stored in the means 20 may moreover be used to make the pneumatic elements used in the system operate. The latter may in fact comprise:
one or more pneumatic valves,
and/or one or more pneumatic jacks, notably for the handling of the parts to be treated, during the loading and the unloading of the chamber 14, or instead to open or close the door 15,
and/or one or more pneumatic pumps.

More generally, all the means that normally implement a supply with additional gas, for example compressed air, may be actuated by the gas stored in the means 20. For example, the valves are normally implemented with a supply of compressed air. The use, for this purpose, of the gas stored in the means 20, makes it possible to eliminate the necessity of supplying such an additional gas. With this aim, a conduit 23 makes it possible to withdraw gas from the means 20; distribution channels, designated globally by the reference 25 in FIG. 2, carry along this withdrawn gas to, for example, the different pneumatic means of the system, notably one or more valves and/or one or more jacks and/or one or more pumps. A pressure reducer may be provided at the outlet of the means 20, on the conduit 23, in order to reduce the pressure with a view to these applications.

This aspect is advantageous compared to a situation where the gas would be withdrawn from the means 6 for supplying one or more pneumatic means. In the latter case, in fact, any leakage of the supply with compressed fluid from a valve or a pneumatic element is going to lead to a leakage of a quantity equal, at the most, to the quantity contained in the means 6. In the solution proposed here (supply with gas from the means 20), the quantity of gas contained in the means 20 is in general much lower than that in the means 6.

Finally, according to the diagram of FIG. 3, it is possible to use some of the gas stored in the means 20 to reinject it into the usual circuit. Gas from the means 20 may thus then be reinjected, in the form of liquefied gas, into the means 6, after having undergone compression by the compressor 3 and potentially liquefaction under the action of the means 7. This step may be carried out during the implementation of a treatment cycle, in hidden time.

The device and the method that have been described above are particularly suitable for the implementation of cleaning by carbon dioxide in the supercritical state. Nevertheless, this device may also be suited for operation with another fluid, for example a pressurised dense fluid, or, again for example, with oxygen or nitrogen, under conditions enabling them to be in the supercritical state (for oxygen: beyond −119° C. and 50 bars; for nitrogen: beyond −147° C. and 34 bars).

In a variant, another fluid may be implemented, for example a fluid chosen from among methane, ethanol, propane, nitrogen protoxide, a fluorinated gas, ammonia, alcohol, ethanol, isopropanol, water.

Furthermore, in combination with one of the fluids already mentioned above, an additive such as a solvent may also be introduced into the chamber 14.

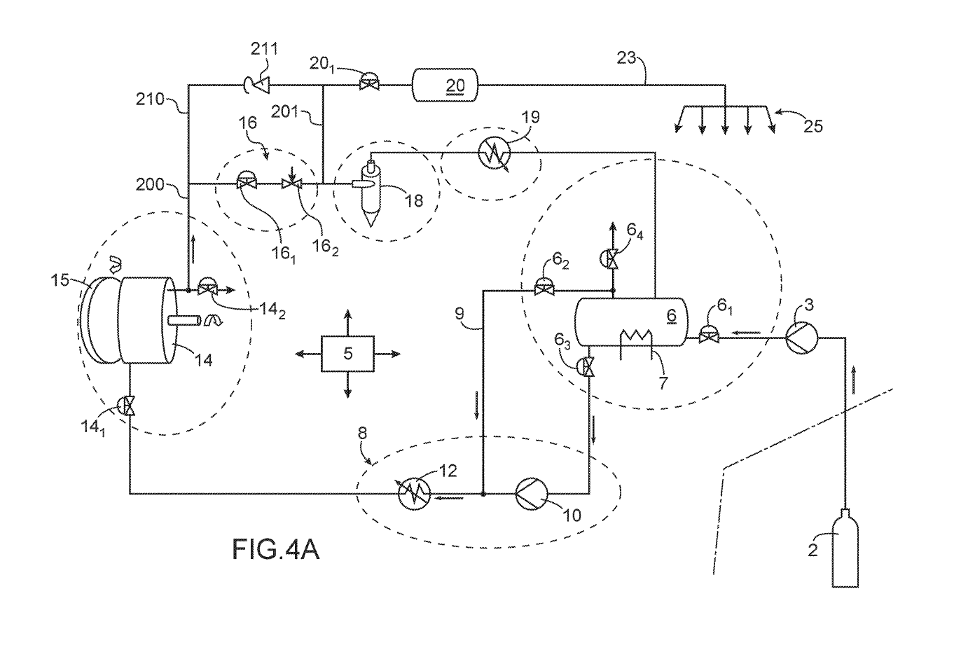

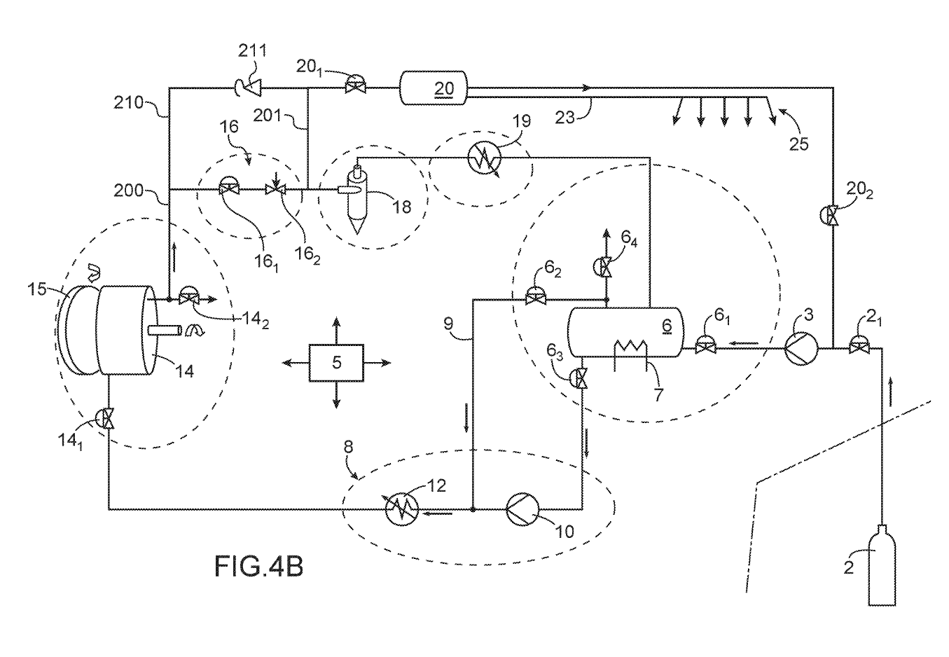

FIGS. 4A and 4B are variants, respectively, of the machines of FIGS. 2 and 3 described above, in which the reservoir 20 is supplied from a point arranged between the regulation valve 16₂ and the separator 18. The gas migrates from the chamber 14 to the means 20 via several conduits 200, 201. This makes it possible to dimension the reservoir for a pressure, for example 60 bars, lower than in the preceding embodiments, because it is protected against overpressure by the means 16₁, 16₂ and by the means 18 in the case where, for example, the valve 20₁ would remain open during the operation of a treatment cycle. Here again, some of the gas stored in the means 20 returns to the chamber 14, along a path opposite to that followed by the gas when it has migrated from the chamber 14 to the means 20. This gas thus goes back via the same conduits 200, 201 but in the opposite sense.

A conduit 210 can connect the outlet of the chamber 14 (or a point upstream of the means 16, in the sense of flow of the fluid from the chamber 14) and the inlet means 20 or the valve 20₁. This conduit may be provided with means 211 forming a non-return valve, which blocks direct flow of the fluid from the chamber 14 to the means 20, but enables flow from the means 20 to the chamber 14. Thus, fluid that flows from the chamber 14 passes necessarily via the means 16; but the opposite is not true, flow from the means 20 to the chamber 14 being able to pass via the conduit 210, to re-join the conduit 200.

A comparative example will now be given.

A cycle of a machine such as that of FIG. 1 (standard machine, with a storage chamber 6 under a pressure of 60 bars) will firstly be considered. The cycle is the following.

All the valves are firstly assumed closed, then the door of the autoclave is opened. The internal reserve 6 is sufficiently full. The steps of the cycle are the following.

1. Closing of the door 15 of the autoclave 14 and the valve 14₂, the autoclave 14 is thus at atmospheric pressure.

2. Opening of the valve 6₂ to begin to fill the autoclave 14 with gaseous CO₂.

3. When the pressure in the autoclave 14 is of the order of 10 bars (or more), the valve 6₂ is closed and the valve 6₃ and the valve 14₁ are opened and the pump 10 is started. The autoclave is thus filled.

4. On reaching the desired working pressure (pressure much higher than the storage pressure, at least 90 bars for example), the valve 16₁ is opened and the flow rate it adjusted with the regulation valve 16₂ to maintain the pressure at the desired value. The CO₂ is potentially cleaned in the separator 18, then it is liquefied by the means 19 and sent back into the internal reserve 6 to be reused.

5. At the end of treatment, the pump 10 is stopped and the valve 14₁ is closed. The emptying of the autoclave into the liquid reserve 6 is continued, up to equality of pressures so as to lose a minimum of CO₂.

6. The valve 16₁ is closed. The pressure in the autoclave is then 60 bars.

7. The valve 14₂ is opened. All the CO₂, then present in the autoclave is lost. When the autoclave is at atmospheric pressure, it is possible to open the door 15 (or, more generally, establish fluid communication between the chamber and the outer atmosphere).

For this example, the losses are of the order of 0.2 kg per litre of autoclave (value that can vary as a function of temperature). The pump 3 completes the internal storage of the quantity lost.

A cycle of a machine according to the invention will now be considered, such as that of FIG. 2, with a recovery volume 20 equal to that of the autoclave 14.

The cycle is the following (it is assumed that CO₂ is a perfect gas and the effect of temperature variations during depressurisations is neglected).

Firstly, an initial filling of the recovery volume 20 may be described.

In this case, at the start of the first cycle the recovery reservoir 20 is at atmospheric pressure.

All the valves are closed, and the door 15 of the autoclave 14 is open. The steps 1-6 described above are carried out. Then the following steps are carried out:

7. Opening of the valve 20₁. The CO₂ is distributed in the two volumes 14, 20, the resulting pressure is 30 bars.

8. Closing of the valve 20₁.

9. The valve 14₂ is opened. All the CO₂ present remaining in the autoclave is lost. When the autoclave is at atmospheric pressure, its door 15 may be opened.

The valve 14₂ has thus been opened at 30 bars, instead of 60 bars, i.e. two times fewer losses.

At the start of the second cycle, the recovery reservoir 20 is thus at 30 bars.

The cycle is then the following.

1. Closing of the door of the autoclave and the valve 14₂, the autoclave is thus at atmospheric pressure.

2. Opening of the valve 20₁, the CO₂ present in the recovery reservoir is distributed into the two volumes; the resulting pressure is 15 bars.

3. Closing of the valve 20₁ and opening the valve 6₃, the valve 14₁ and starting up the pump 10. The autoclave is thus filled with dense fluid.

4. Steps 4 to 6 are identical to those already described above.

7. Opening of the valve 20₁. The CO₂ is distributed in the two volumes; the resulting pressure is (60+15)/2=37.5 bars (identical volumes).

At the start of the third cycle, the recovery reservoir is at 37.5/2=18.75 bars.

The cycle remains the same but, at the end, the autoclave is opened at the pressure of (60+18.75)2=39.4 bars.

The pressure limit in the reservoir 20 is 40 bars, i.e. a saving of CO₂ of 33%(=1-40/60).

Whatever the envisaged embodiment, means may be provided for heating or thermostatically controlling (or maintaining at constant temperature) the second storage means, such that, or in order that, the gas that is stored therein does not condense and/or does not liquefy.

Whatever the envisaged embodiment, apart from the means above, a device according to the invention may comprise means 5, of electronic and/or computer type, for controlling and regulating the operation of each of the components of the machine, notably the pumps and the valves, according to a programmed sequence of steps.

These controller forming means 5 may comprise circuits, which make it possible to send to each of the components of the machine instructions and/or voltages making it possible to run them according to a predefined sequence. In particular, these means are going to make it possible to implement a cleaning cycle as described above, and notably to regulate the steps of transfer of gas between the autoclave and the discharge storage means 20. In a more precise manner, these means are going to control the durations of the opening or the closing of the valves 20₁, 16₁, 20₂, but also the other valves of the system, and/or the operating durations of the pump 10 and/or the compressor 3.

This assembly 5 may moreover potentially receive signals corresponding to measurements carried out using one or more pressure sensors, for example arranged to measure the pressure in the autoclave 14, or in the storage means 20, and can process them and use them for the control of one or more of the components of the machine.

This controller assembly 5 may communicate with a user interface to inform a user of the state of the machine, in particular of its operating cycle.

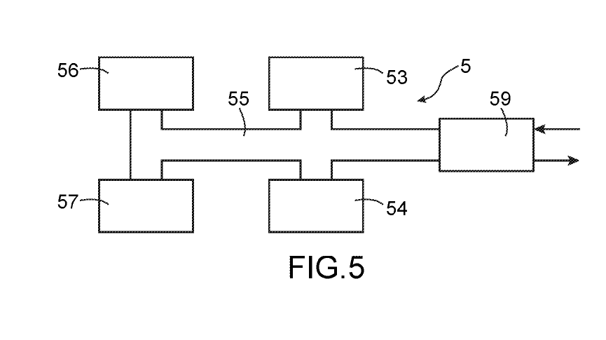

An example of embodiment of these means 5 is described below in a more precise manner with reference to FIG. 5.

In this example, these means comprise means 53 for memorising instructions relative to the processing of data, for example to carry out a method of the type described above.

According to an example of embodiment, the controller 5 comprises a central unit, which itself includes a microprocessor 56, a series of non-volatile memories and RAM 57, peripheral circuits, all these elements being coupled to a bus 55. Data may be stored in the memory zones, notably data for implementing a method according to the present invention or for controlling a machine according to the present invention. Means 59 are going to make it possible to manage the flow of input and output data, from other components of the machine, and in the direction thereof.

In a variant, this controller assembly 5 may be realised in the form of a FPGA (Field Programmable Gate Array) or an ASIC (Application Specific Integrated Circuit).

The means 54, which may comprise visualisation means, may potentially enable a user to interact with the operation of a machine according to the invention, for example by intervening on a particular step of an operating cycle.

A machine according to the invention, and a method for operating such a machine, such as described above, makes it possible to make savings of components, operating time, and material used.

The invention has been described within the scope of the implementation of a pressurised dense fluid, notably carbon dioxide in the supercritical state. It may apply to other fluids, in particular nitrogen or oxygen or any other of the fluids already cited.

The invention has been described above for a cleaning method.

But other methods may be implemented using a device or a method according to the invention, the appropriate fluid being used in the dense state, or even supercritical state. For each of the different examples cited below, it is possible to use CO₂.

In all cases, the fluid used, dense or supercritical, immerses the treated parts. The contact, more or less long, between the latter and the fluid brings about the sought after treatment.

This is the case, for example, of a debinding method or an extraction method (cleaning being a particular case of extraction).

A debinding method makes it possible to extract a binder from a part made of an alloy, for example from a powder such as a powder assembled in a paraffin, and/or to extract any binder suited to the manufacture of the alloy.

Again for example, a method for extracting one or more natural substances may be implemented in particular in the pharmaceuticals or food processing industry.

An extraction method, or instead degreasing, may also be implemented to treat natural wool, in order to extract suint therefrom. Usually, this type of treatment is carried out by perchlorethylene or water.

The invention may also be used in methods of impregnation or input of product transported by the dense or supercritical fluid within the material to be treated.

The invention also make it possible to implement a sterilisation method (for example in the food processing or medical field), at low temperature, based on the penetrability of the gas, at high pressure, which is going to be able to penetrate into the material to be treated and to neutralise, or kill, infectious agents.

More generally, any type of part may be treated by a method according to the invention.

The materials, which can be treated by the method of the invention, are generally solid materials, for example:
metals,
metal alloys, potentially plated, such as aluminium, titanium, steel, stainless steel, copper, brass, and any other alloy, or plated metal,
ceramic materials, polymer materials, powders, notably powders of the materials cited above,
textile materials, natural or synthetic, or instead leather,
rectification sludges, coming for example from a bar turning or machining method.

The treated parts may be, for example:
parts from the aeronautics industry, or automobile and more generally mechanical industries,
clock making and/or micromechanical parts,
electric or electronic connectors,
components made of semiconductor materials from the microelectronics industry,
medical or surgical apparatus or tools, etc.
clothes, or natural materials used in the textile industry, for example wool, or leather.

What is claimed is:

1-19. (canceled)

20. Treatment device using a dense fluid, notably a supercritical fluid, comprising:
a) a treatment chamber, for receiving the parts to be treated, provided a door for establishing fluid communication then isolating the inside of said chamber with respect to the outer atmosphere,
b) a circuit for supplying supercritical fluid to said chamber, comprising a fluid storage chamber,
c) a storage reservoir, for storing some of the gas contained in the chamber, in gaseous form, after a treatment step and before fluid communication is established between the chamber and the outer atmosphere,
d) a valve for establishing fluid communication between said cleaning chamber and said second storage reservoir and for enabling fluid circulation, from the treatment chamber to said second storage reservoir then, along a reverse path, from the second storage reservoir to the cleaning chamber.

21. Device according to claim 20, said storage reservoir being arranged in parallel with a depressurizer at the outlet of said chamber.

22. Device according to claim 20, a gas depressurizer at the outlet of said chamber being arranged between the outlet of said chamber and the inlet of said storage reservoir.

23. Device according to claim 20, the ratio between the internal volume of said storage reservoir and the internal volume of said treatment chamber being at least equal to 1.

24. Device according to claim 20, further comprising a circuit conveying at least some of the fluid stored in the storage reservoir to the circuit supplying said chamber with supercritical fluid.

25. Device according to claim 24, further comprising a controller programmed to convey at least some of the fluid stored in the storage reservoir to the circuit for supplying said chamber with dense fluid during a treatment cycle by the treatment chamber.

26. Device according to claim 20, further comprising at least a conduit for conveying at least some of the fluid stored in the second storage reservoir to one or more pneumatic control device.

27. Device according to claim 26, said pneumatic control device comprising at least one of a pneumatic valve, a pneumatic jack, a pneumatic pump.

28. Device according to claim 20, further comprising a heater of said storage reservoir.

29. Treatment method using a supercritical fluid comprising, in this order:
a) the introduction of at least one first part or element to be treated into a chamber, provided with a door for establishing fluid communication with the outer atmosphere, then closing said door,
b) then the supply of supercritical fluid to said chamber and the treatment of said part,
c) then the storage of some of the gas contained in the treatment chamber, in a storage reservoir, in gaseous form at a pressure P₂ lower than that (P₁) which exists in the chamber, after the treatment step b) and before fluid communication is established between the inside of said chamber and the outer atmosphere,
d) establishing fluid communication between the inside of said chamber and the outer atmosphere,
e) the introduction of at least one second part to be treated into said chamber, then closing the door,
f) then the injection, into said chamber, of at least some of the gas stored in said storage reservoir, the gas contained in said chamber then being at a pressure P₃ lower than the storage pressure P₂ in the storage reservoir.

30. Method according to claim 29, further comprising an injection of some of the gas stored in said storage reservoir into said fluid storage chamber, arranged upstream of the circuit for bringing a fluid to the supercritical state.

31. Method according to claim 30, said injection of some of the gas stored in said storage reservoir into said fluid storage chamber being carried out, at least in part, during the treatment of said part.

32. Method according to claim 29, further comprising the actuation of at least one pneumatic control device using some of the gas stored in said storage reservoir.

33. Method according to claim 32, said pneumatic control elements comprising at least a pneumatic valve and/or a jack and/or a pump.

34. Method according to claim 29, said storage reservoir and said valve being arranged in parallel with a depressuriser of gas at the outlet of said chamber.

35. Method according to claim 29, said storage reservoir and said valve being arranged at the outlet of a depressuriser of gas at the outlet of said chamber.

36. Treatment method using a dense fluid, notably supercritical, comprising the implementation of a device according to claim 20.

37. Method according to claim 29, said part to be treated being at least in part made of a metal material, and/or a metal alloy, and/or a ceramic material, and/or a semiconductor material, and/or a textile material and/or a natural material.

38. Method according to claim 29, the treatment being an extraction treatment, for example cleaning or degreasing, or debinding, or sterilisation.

39. Treatment device using a dense fluid, notably a supercritical fluid, comprising:
a) a treatment chamber, for receiving the parts to be treated, provided with means for establishing fluid communication then isolating the inside of said chamber with respect to the outer atmosphere,
b) means for supplying supercritical fluid to said chamber, comprising first fluid storage means,
c) second storage means, for storing some of the gas contained in the chamber, in gaseous form, after a treatment step and before fluid communication is established between the chamber and the outer atmosphere,
d) means for establishing fluid communication between said cleaning chamber and said second storage means and for enabling fluid circulation, from the treatment chamber to said second storage means then, along a reverse path, from the second storage means to the cleaning chamber.
